(19) United States
(12) Patent Application Publication
(10) Pub. No.: US 2007/0232067 A1
(43) Pub. Date: Oct. 4, 2007

(54) Semiconductor Fabrication Method and Etching System

(76) Inventors: Kousa Hirota, Tokyo (JP); Masahito Mori, Tokorozawa-shi (JP); Naoyuki Kofuji, Tokyo (JP); Naoshi Itabashi, Tokyo (JP); Toshio Masuda, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/692,241

(22) Filed: Mar. 28, 2007

(30) Foreign Application Priority Data
Mar. 30, 2006 (JP) 2006-095731
Mar. 19, 2007 (JP) 2007-071122

(51) Int. Cl. H01L 21/302

(52) U.S. Cl. 438/689

(57) ABSTRACT

The invention provides a semiconductor fabrication method comprising a deposition step for depositing a laminated film on a semiconductor substrate having a region in which a mask pattern is formed sparsely and a region in which the mask pattern is formed densely, a lithography step s1 for forming a mask pattern, a cleaning step S11C for removing deposits in the apparatus, a trimming step S3 for trimming the mask pattern, and dry etching steps S4 and S5 for transferring the mask pattern on the laminated film, wherein a seasoning step S11S followed by a deposition step S2 is introduced either before or after the trimming step S3.

The present application is based on and claims priorities of Japanese patent application No. 2006-095731 filed on Mar. 30, 2006 and Japanese patent application No. 2007-071122 filed on Mar. 19, 2007, the entire contents of which are hereby incorporated by reference.

### BACKGROUND OF THE INVENTION

1. Field of the Invention

The present invention relates to a fabrication method of a semiconductor apparatus including a MOS (metal oxide semiconductor) transistor utilizing electrons or holes as carriers, and especially relates to a dry etching method for stably forming gate electrodes of fine dimension with various pattern densities.

2. Description of the Related Art

Along with the recent advancement in integration and speed of semiconductor integrated circuits, there are demands for further miniaturization of gate electrodes. However, since even a small fluctuation of dimension of the gate electrode causes the source-drain current or the leak current during standby to be greatly varied, it is extremely important to maintain a high dimension accuracy of the gate electrode.

A general process for forming the gate electrode will be described. A laminated film is formed via a deposition step composed of depositing on a silicon (hereinafter referred to as Si) substrate an oxide silicon (hereinafter referred to as SiO₂) gate insulating film, a polysilicon (hereinafter referred to as Poly-Si) film for forming the gate electrode, a BARL (bottom antireflection layer) film functioning as the antireflection film, and a photoresist (hereinafter also referred to as PR) layer, which are deposited in the named order. Thereafter, an exposing step using light sources such as ArF and F₂, a baking step and a lithography step composed for example of an image processing step are performed to complete the mask pattern. Currently, since the gate electrode dimension is required to be processed to a dimension shorter than the wavelength of light used in the exposure process (193 nm, 157 nm), the forming of gate electrodes of fine dimension is realized by performing a trimming step of the PR film using an etching apparatus following the lithography step to thereby trim the mask dimension. Thereafter, the trimmed photoresist is used as the mask to perform a BARL etching step and a dry etching step which is the gate etching step to complete the gate electrode.

The processes from the trimming step of the mask pattern to the gate etching step are performed in the etching apparatus. For example, the etching apparatus introduces etching gas into a vacuum processing chamber, generates plasma discharge under reduced pressure, causes radicals and ions generated in the plasma to react with the surface of the wafer which is the object to be processed and performs etching. At this time, the etching process is performed based on a plurality of set conditions called a recipe. The apparatus parameters defined in the recipe include, for example, gas species, gas pressure, gas flow rate, plasma source power, RF (radio frequency) bias power for drawing ions to the substrate, electrode temperature for determining the temperature of the wafer stage, and processing time.

There are problems of pn difference and sparse-dense difference in the etching of gate electrodes. Pn difference is the difference in completed dimension and profile occurring between a pMOS portion and an nMOS portion.

On the other hand, a sparse dense difference refers to the difference in the mask pattern dimension in the region in which the mask pattern is formed sparsely (hereinafter referred to as sparse pattern dimension) and the mask pattern dimension in the region in which the mask pattern is formed densely (hereinafter referred to as dense pattern dimension). In the etching of the gate electrode, it is required that the gate electrode is finally processed to a dimension having a target sparse dense difference. Therefore, the gate etching process must be performed while considering the above-mentioned problems of pn difference and sparse dense difference, and at the same time, it must prioritize in realizing a perpendicular processing of the gate electrode from the viewpoint of performance of the MOS element, so that the accuracy of processing the sparse pattern dimension and the dense pattern dimension of the mask and the control technique thereof becomes important in order to achieve the desired sparse gate electrode dimension and dense gate electrode dimension.

However, in a semiconductor integrated circuit, a dense pattern region having a large area density such as the memory or the logic unit and a sparse pattern region having a small area density such as the peripheral circuitry portion exist on the same wafer surface. Therefore, the mask dimension control is not easy. One cause thereof is described hereafter.

FIG. 19(a) is a cross-sectional view of a common wafer prior to forming the gate electrode composed from the lower layer of an Si substrate 11, an SiO₂ gate insulating film 12, a poly-Si gate electrode film 13, a BARL 14 and a PR mask 15 having a sparse pattern 151 and a dense pattern 152. When the wafer is subjected to a trimming process, since the probability of radicals having a transverse motor component entering between the patterns is lower in the dense pattern 152 of the PR mask than the sparse pattern 151 of the PR mask, the trimming quantity of the sparse pattern 151A having been subjected to trimming process becomes greater than that of the dense pattern 152A having been subjected to trimming process, as illustrated in FIG. 19(b). Here, the trimming quantity is defined as the difference (Xi−yi) between an initial dimension Xi of the pattern and the pattern dimension Yi after the trimming step, taking the sparse pattern as an example. (The trimming quantity of the dense pattern is defined as Xd−Y_{d}.) The sparse dense difference is defined as the difference Yi−Y_{d} between the sparse pattern dimension Yi and the dense pattern dimension Yd after the trimming.

In general, during the trimming step in which the radical reaction is dominant, if the mask pattern dimension having been completely exposed is the same for the sparse pattern and the dense pattern, the sparse pattern 151A after the trimming step becomes smaller in dimension than the dense pattern 152A after the trimming step. Such mechanism makes the dimension control of the sparse pattern and the dense pattern difficult.

Currently, however, even though it is difficult to control the dimensions of the sparse pattern and the dense pattern, the thinning of the gate electrodes has advanced, and it has become necessary to change the completed dimension of the gate electrode from the mask dimension of the exposure limitation according to purpose. Table 1 illustrates the target mask dimension, the trimming quantity and the sparse dense difference with respect to the initial mask dimension of portions A, B and C. For convenience, it is assumed that perpendicular etching is possible in the BARL etching step and the gate etching step following the trimming step, and that the mask dimension after trimming equals the gate electrode dimension.

TABLE 1

| | | |
|---|---|---|
| A | B | C |

| | | | | | | |
|---|---|---|---|---|---|---|
| Initial mask | 100 | nm | 100 | nm | 100 | nm |
| dimension | | | | | | |
| Target mask | 95 | nm | 45 | nm | 25 | nm |
| dimension | | | | | | |
| Trimming | 5 | nm | 55 | nm | 75 | nm |
| quantity | | | | | | |
| Sparse dense | 0 +− 1 | nm | 0 +− 1 | nm | 0 +− 1 | nm |
| difference | | | | | | |

According to the ITRS road map, the conditions of table 1B corresponds to a LSTP (low standby power) 45 nm gate electrode to be achieved in the year 2006 and conditions of C corresponds to a HP (high performance) 25 nm gate electrode to be achieved in the next generation, or year 2007. The requirements A, B and C cannot be realized according to the prior art trimming technology having only a narrow control range. With reference to Table 1, the control method according to the prior art technology will be described below.

FIG. 20 is a graph showing the relationship between the sparse mask dimension and the dense mask dimension upon performing the trimming step when the completely exposed sparse mask and dense mask dimensions are both 100 nm. In the graph, a dotted line C1 is plotted to show where the sparse dense difference is zero. Further, conditions A, B and C demanded in Table 1 are shown in the graph.

A relational curve C2 of the sparse mask dimension and the dense mask dimension according to a trimming condition in which the sparse dense difference is greatest, and a relational curve C3 of the sparse mask dimension and the dense mask dimension according to a trimming condition in which the sparse dense difference is smallest are shown in the graph. When the gas mixture ratio or the like is varied, the area surrounded by the vertical axis, the relational curve C2 and the relational curve C3 is the actually trimmable area. Only requirement condition A fulfills the conditions shown in Table 1. Requirement conditions B and C are deviated from the trimmable area.

In order to realize requirement condition B that could not be trimmed, a method called an OPC (optical proximity correction) is adopted to correct the mask dimension intentionally from the dimension of the device pattern to be formed on the wafer. The prior art trimming adopting the OPC technology with the completely exposed sparse mask dimension set to 100 nm and that of the dense mask dimension set to 90 nm is illustrated in FIG. 21. Similarly, the area surrounded by the vertical axis, the curve C21 of the large sparse dense difference and the curve C31 of the small sparse dense difference is the actually trimmable area.

The trimming where sparse dense difference is zero is realizable at an intersection between the dotted line C1 representing zero sparse dense difference and either the curve C21 of the large sparse dense difference or the curve 31 of the small sparse dense difference.

Only requirement condition B fulfills the conditions shown in Table 1. Requirement conditions A and C are deviated from the trimmable area.

In other words, according to the above technology, in order to fulfill all the conditions shown in Table 1, it is necessary to prepare two masks with different sparse and dense pattern dimensions for each of the requirement conditions.

Further, as a method for controlling the dimension of the sparse pattern and the dimension of the dense pattern, a method is proposed to realize the target pattern dimension with high stability through use of a trimming process using a mixed gas composed of a gas promoting etching and a gas suppressing etching (refer for example to patent document 1). In this case, the control must be performed by controlling the time of over etching (OE) and main etching (ME) of the BARC (bottom anti-reflection coating) and O₂ fraction, or by controlling the SO fraction and He dilution rate.

On the other hand, in mass production, there are cases in which the gate electrode dimensions of the sparse pattern and dense pattern deviate from the target dimension. There are two main causes of such fluctuation, which are mentioned below.

One cause is known to be the occurrence of mask dimension fluctuation caused by the deactivation of acid catalyst and atmosphere depending on the time from the ending of exposure to the PEB (post exposure bake) in the mass production of mask patterns in a lithography step (refer for example to patent document 2). Along therewith, the fluctuation of dimension of gate electrode in the lower layer occurs.

Another cause is the occurrence of dimension fluctuation of the gate electrode caused by the change of trimming performance with respect to the trimming material or the change of etching performance with respect to the etching material accompanying the change of environment in the etching device that occurs with the passing of time.

One proposed method for controlling the sparse dense difference utilizes a step of widening the pattern width of the mask layer by depositing plasma reaction products on the side walls of the mask layer having been patterned in advance, and a step of reducing the pattern width by trimming the widened pattern width (refer for example to patent document 3).

[Patent Document 1] Japanese Patent Application Laid-Open Publication No. 2005-45214

[Patent Document 2] Japanese Patent Application Laid-Open Publication No. 11-194506

[Patent Document 3] Japanese Patent Application Laid-Open Publication No. 2005-129893

### SUMMARY OF THE INVENTION

The above-mentioned prior art has the following drawbacks.

(1) According to the prior art sparse dense control method, the time controllability and the reproducibility were not good, so it was not possible to obtain a desired sparse dense pattern dimension with high accuracy.

(2) In the mass production of a mask pattern in a lithography step, by the fluctuation of dimensions of the completely exposed sparse pattern and dense pattern that vary with time, it becomes difficult to obtain the desired sparse and dense pattern mask dimensions.

(3) By the condition in the reactor of the etching apparatus gradually varying with time, the dimensions of the sparse pattern and dense pattern of the material to be trimmed or material to be etched are also fluctuated, and as a result, it becomes difficult to obtain the desired mask dimension and gate electrode dimension in the long term.

(4) Regarding the increase of sparse/dense mask dimension in the deposition step, the relationship between the sparse/dense mask dimension and deposition time was not known for the wafer having a mask dimension or mask density that has never been subjected to the deposition step.

The object of the present invention is to provide a semiconductor fabrication method capable of solving the above-mentioned problems by suppressing the long-term fluctuation of the completely exposed sparse and dense pattern dimensions and the gate electrode dimension, and to enable the independent control of the dimensions of the sparse and dense patterns to be reproduced with high accuracy.

The problem mentioned in item (1) can be solved by introducing a seasoning step followed by a deposition step either prior to or subsequent to a trimming step of the mask pattern. It is known that the wall surface status including the deposits and the surface condition in the plasma processing chamber affects the gate dimension. In other words, it is necessary to introduce a seasoning step immediately prior to the deposition step in order to maintain a constant wall surface status after the deposition step.

Moreover, in the deposition process performed during the deposition step, the dimension shift of the sparse mask pattern (hereinafter called sparse dimension shift, also referred to as CD or critical dimension shift) becomes greater in principle than the dimension shift of the dense mask pattern (hereinafter called dense dimension shift), contrary to the trimming process during the trimming step. The difference between the sparse dimension shift and the dense dimension shift can be controlled by the combination of gas species, gas flow rate, gas pressure, electrode temperature, RF bias power and time. The present invention characterizes in utilizing the mutual difference between the sparse dimension shift and dense dimension shift during the deposition step and the trimming step to perform control so as to obtain the desired sparse mask dimension, dense mask dimension and gate electrode dimension of the sparse and dense masks.

The problem mentioned in item (2) can be solved as follows. The present invention characterizes in checking the fluctuation quantity of the completely exposed sparse mask and dense mask dimensions via a dimension measurement device such as a SEM, and to perform control of the deposition step and the trimming step so as to suppress such fluctuation in order to achieve the target mask dimension in the sparse pattern region (hereinafter referred to as sparse mask) and the target mask dimension in the dense pattern region (hereinafter referred to as dense mask). This is a so-called feed forward control.

The problem mentioned in item (3) can be solved as follows. After completing gate etching, the dimension fluctuation of the gate electrode is detected by measuring the gate dimension of the sparse mask and the electrode dimension of the gate of the dense mask via an SEM and the like. The present invention characterizes in correcting the conditions of the deposition step and the trimming step for the subsequent wafer or subsequent lot, so as to perform control to suppress long term fluctuation of the electrode dimensions of the sparse mask and dense mask gates. This is a so-called feed back control.

The problem mentioned in item (4) can be solved as follows. The prevent inventors have discovered that there are two rules in the increase of sparse/dense mask dimensions during the deposition step. We have discovered that the CD bias which is a value obtained by subtracting the initial sparse/dense mask dimension from the sparse/dense mask dimension after deposition can be expressed as a function of time and space (nm) which is the inter-mask distance. The other rule that we have discovered is that the sparse/dense mask dimension can be increased linearly with respect to the deposition time. The present invention utilizes the fact that the sparse/dense mask dimension can be estimated based on these two rules, and enables to realize the desired sparse/dense mask dimension for any wafer having an arbitrary sparse/dense mask dimension and density.

The effects achieved by the typical characteristics of the present invention disclosed herein are described briefly in the following.

With respect to each target mask dimension shown in Table 1, by performing a deposition step and a trimming step and mutually utilizing the difference between the dimension shift of the sparse mask and the dimension shift of the dense mask of each step, it becomes possible to obtain the desired sparse and dense mask dimensions and gate electrode dimension with good reproducibility.

Moreover, by detecting the fluctuation quantity of the completely exposed sparse mask dimension and dense mask dimension using a dimension measurement device such as the SEM, and by performing the deposition step and the trimming step while varying at least the gas species, the gas flow rate, the gas pressure, the electrode temperature, the RF bias power or the time so as to suppress the fluctuation, it becomes possible to stably obtain the target sparse and dense mask dimensions and gate electrode dimension.

In addition, by detecting the fluctuation quantity based on the measurement result of the electrode dimensions of the sparse and dense masks after gate etching, and by determining or correcting the conditions of the deposition step and the trimming step for the subsequent wafer or lot based on the detected information, it becomes possible to suppress long term fluctuation of the sparse gate electrode dimension and dense gate electrode dimension and to stably obtain the target sparse gate electrode dimension and dense gate electrode dimension.

### BRIEF DESCRIPTION OF THE DRAWINGS

FIG. 1 is a flowchart of a semiconductor fabrication method according to a first embodiment of the present invention;

FIG. 2 is a graph showing the measurement result of a sparse/dense CD bias when four wafers are processed continuously with the time for the deposition step fixed to 390 seconds;

FIG. 3(a) is a graph illustrating the transition of deposition curve and the transition of sparse and dense mask dimensions after performing trimming upon performing a deposition step using CHF₃, a pressure of 0.2 Pa, a flow rate of 60 ml/min and an RF bias power of 10 W followed by the trimming step;

FIG. 3(b) is a graph illustrating the transition of sparse and dense mask dimensions in the deposition step and trimming step for realizing a 25 nm mask dimension and zero sparse dense difference according to requirement condition C shown in table 1;

FIG. 3(c) is a graph showing that the control range of sparse dense difference has been widened according to the present invention;

FIG. 3(d) is a graph illustrating the transition of deposition curve and the transition of sparse and dense mask dimensions after performing trimming upon performing a deposition step using CHF₃, a pressure of 2 Pa, a flow rate of 100 ml/min and an RF bias power of 0 W followed by the trimming step;

FIG. 4 is a frame format showing the method for independently controlling the dimensions of a sparse mask and a dense mask according to the present invention;

FIG. 5 is a cross-sectional view describing the transition of the mask pattern before and after the deposition step in which the adsorption probability is high;

FIG. 6 is a cross-sectional view describing the transition of the mask pattern before and after the deposition step in which the adsorption probability is low;

FIG. 7 is a frame format describing how the deposition quantity to the sparse pattern and the dense pattern is controlled via RF bias;

FIG. 8 is a cross-sectional view of the wafer after performing the deposition step under a condition in which the adsorption probability is high;

FIG. 9 is a flowchart of the semiconductor fabrication method according to a second embodiment of the present invention;

FIG. 10 is a flowchart of the semiconductor fabrication method according to a third embodiment of the present invention;

FIG. 11 is a flowchart of the semiconductor fabrication method according to a fourth embodiment of the present invention;

FIG. 12 is an example of a cross-sectional view illustrating the structure of a wafer composed, from the bottom layer, of a gate electrode film, a BARC and a PR mask;

FIG. 13 is an example of across-sectional view of the etching apparatus for carrying out the present invention;

FIG. 14 is a view illustrating the definition of space;

FIG. 15 is a graph showing the experimental value of deposition time dependency (90, 210 and 390 seconds) of CD bias in which the space equals 280, 440 and 3000 nm, and the estimated value from a sparse dense gradient expression;

FIG. 16 is a graph showing the result of examining the relationship between the increase of sparse/dense mask dimension (referred to as sparse/dense CD bias) using the initial mask dimension as reference and deposition time upon performing the deposition step according to the flowchart of FIG. 1 subsequent to the seasoning step using a deposition gas of CHF3, a pressure of 0.2 Pa, a flow rate of 60 ml/min and an RF of 5 W;

FIG. 17 is a frame format of the sparse mask pattern at a certain time during the deposition step;

FIG. 18 shows one example of a view illustrating the method for determining an end point in an arbitrary space;

FIG. 19 is across-sectional view illustrating the structure of a wafer before and after performing the trimming step;

FIG. 20 is a trimming graph according to the prior art when the initial dimension is 100 nm for both sparse and dense portions; and

FIG. 21 is a trimming graph according to the prior art when the initial dimension is 100 nm for the sparse portion and 90 nm for the dense portion.

### DETAILED DESCRIPTION OF THE PREFERRED EMBODIMENTS

Now, the preferred embodiments of the present invention will be described.

### Embodiment 1

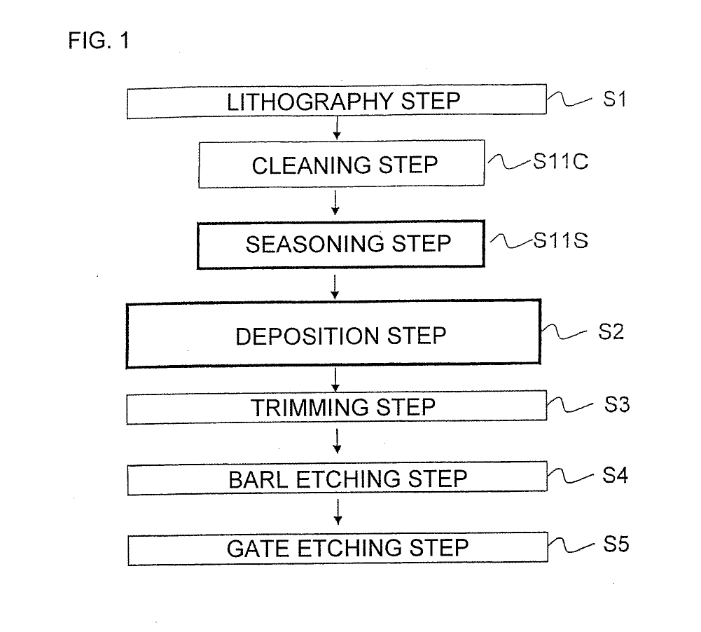

FIG. 1 is a flowchart showing the process for independently controlling the dimensions of a sparse mask and a dense mask according to the first embodiment of the present invention. The process is described along this flow and with reference to relevant drawings. At first, if sparse and dense mask patterns are formed during a lithography step S1, the result of performing, subsequent to a cleaning step S11C, a seasoning step S11S according to the present invention followed by a deposition step S2 will be described.

In the seasoning step, a Si wafer is processed under a processing condition in which CHF₃ gas is used as deposition gas, the pressure is set to 0.2 Pa, the flow rate is set to 60 ml/min and the RF bias power is set to 5 W. By introducing this seasoning step, prior to starting the deposition step, the status of the wall surface of the apparatus becomes substantially equal to the status thereof during the deposition step. In other words, it is preferable that the processing conditions of the seasoning step and the deposition step are the same so that the statuses of the wall surface are substantially equal. However, as long as the statuses of the wall surfaces are substantially equal, it is possible to use difference process conditions for the two steps. Moreover, if the deposition on the electrode surface is within a range so as not to cause any problem for the chucking of the wafer, it is not necessary to use the Si wafer. In other words, the process can be performed in a waterless manner. Moreover, it is possible to use wafers other than the Si wafer.

The end point of the seasoning step is set to a point at which the overall emission intensity which is a sum of all the emission intensities of the wavelengths ranging from 200 nm to 900 nm measured using an OES (optical emission spectroscopy) is saturated. According to the present experiment, the emission intensity was gradually increased with time, and was saturated at approximately 180 seconds. This is considered to mean that there is no more change in radicals in the plasma and that the condition has reached a certain constant condition. At this time, if it is possible to check the status of the carbon depositing on the wall surface, it is not necessary to specifically use the emission intensity of this wavelength range, and a C-based emission intensity can be used instead, for example. Moreover, contrary to the C-based emission intensity, there are radicals in the emission spectrum that are reduced with time, so that whether to set the end point at a point where the emission intensity is increased or where the emission intensity is reduced naturally differs according to the emission species being used. After the seasoning step, the wall surface is covered with deposits and the wall surface status will be in some sort of a stabilized status.

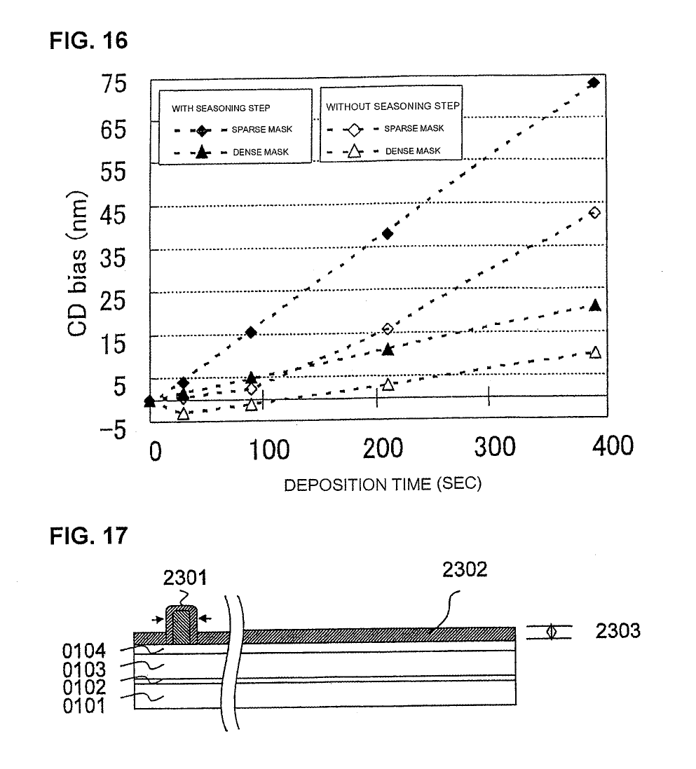

FIG. 16 shows a graph of the result of examining the increase of sparse/dense mask dimension using the initial mask dimension as reference (referred to as a sparse/dense CD bias) and the deposition time when the deposition step following the seasoning step in the flowchart of FIG. 1 is performed using CHF₃ as the deposition gas, a pressure of 0.2 Pa, a flow rate of 60 ml/min and a RF bias power of 5 W. In addition, a case is also shown in which the seasoning step is not introduced in the flowchart of FIG. 1, that is, the deposition step is performed immediately after the cleaning step. In the graph, the sparse/dense CD bias is shown via plots of black rhombuses and triangles for the case in which the seasoning step is performed. On the other hand, the sparse/dense CD bias is shown via plots of outlined rhombuses and triangles for the case in which the seasoning step is not performed. Upon comparing the data for the cases with and without the seasoning step, the linearity of the sparse/dense CD bias is not good with respect to the deposition time for the case in which the seasoning step is not performed, and it is recognized that by introducing the seasoning step, the linearity of the time dependency of the sparse/dense CD bias is greatly improved. For example, according to the case where the seasoning step is not performed, during the zero to 90 seconds constituting the former half of the deposition time, the sparse pattern showed an increase of 2 nm, whereas during the 90 seconds starting from 210 seconds, it showed an increase as much as 15 nm. On the other hand, according to the case where the seasoning step is performed, during the zero to 90 seconds, the sparse pattern showed an increase of 16 nm, whereas during the 90 seconds starting from 210 seconds, it also showed an increase of 16 nm. In other words, when the seasoning step is performed, the gradients of the sparse/dense CD bias were substantially constant regardless of the deposition time.

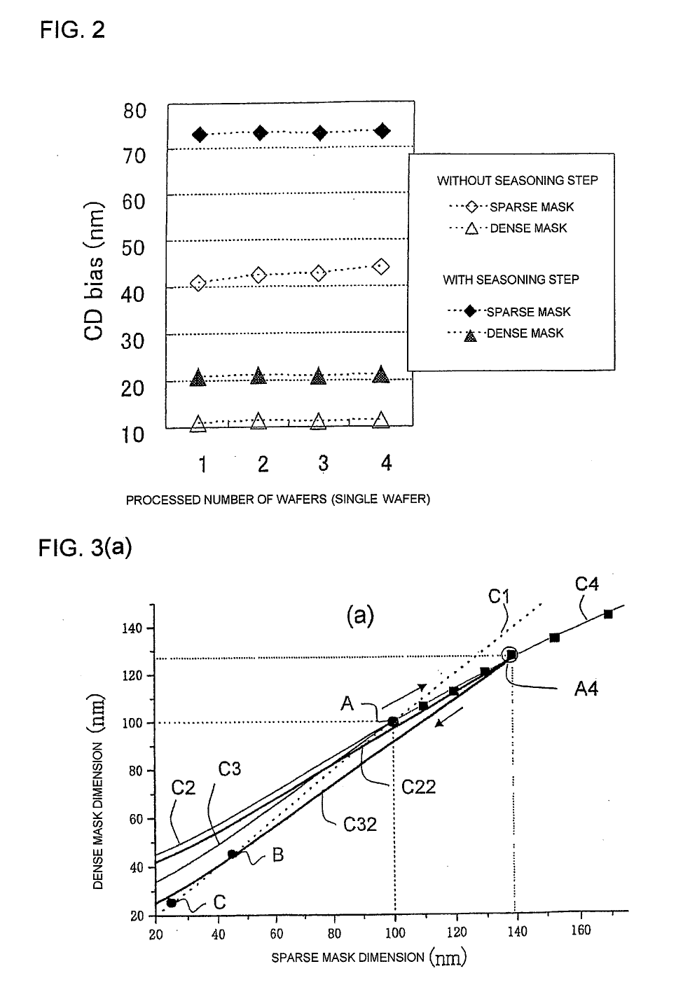

Furthermore, FIG. 2 shows a graph of the measurement result of the sparse/dense CD bias upon processing four wafers continuously with the deposition step time fixed to 390 seconds according to the flowchart of FIG. 1 of the present invention. When the seasoning process was performed (according to the present invention), the sparse/dense CD bias was not fluctuated with respect to the processed number of wafers. The fluctuation width was about 0.5 nm. On the other hand, when the seasoning process was not performed, the sparse/dense CD bias was fluctuated for approximately 2 to 3 nm with the processed number of wafers. This fluctuation quantity is too large in view of the recent microfabrication demands, so it is recognized that a seasoning step must always be performed before the deposition step.

It is considered that the necessity of the seasoning step is deeply related to the difference in wall surface statuses in the plasma processing chamber after the cleaning step and during the deposition step. During the deposition step, when CF-based deposition radicals deposit on the wafer, the radicals also deposit on the wall surface of the processing chamber. In other words, after starting the deposition step, the wall surface is gradually changed from the status immediately after the cleaning step to the status in which deposits are deposited thereon. On the other hand, a mechanism is proposed in which the change in wall surface status causes change in the balance of radicals and ions in the processing chamber. For example, when the Cl radicals in the plasma enter the wall surface, it is known that the percentage in which the radicals are recombined as Cl₂ varies by whether or not there are deposits on the wall surface. Therefore, even according to this experiment, such phenomenon is estimated to have occurred. In other words, when there is no seasoning step, the change in the gradient of the deposition time with respect to the CD bias according to the passing of deposition time is considered to have been caused by the change in CF-based deposits on the wall surface leading to the change in composition of radicals and ions. If the wall surface status immediately after the cleaning step and the wall surface status during the deposition step are substantially the same, the gradient of the deposition time with respect to the CD bias of each deposition time will be equal. This is the effect of introducing a seasoning step prior to the deposition step.

The above-mentioned problem occurs especially in an apparatus for etching small amounts of a large variety of wafers. This is because the compositions and quantities of reaction products generated during etching of each wafer may differ greatly, which causes the wall surface status containing the reaction products adhered on the wall surface to be varied greatly.

As described, by performing a deposition step following the seasoning step as described in FIG. 1 of the present invention, the linearity of the time dependency of the sparse/dense CD bias is improved, and it becomes possible to realize the desired sparse dense mask dimension with high accuracy with respect to time and with good reproducibility.

In the present case, the deposition step and the seasoning step are performed using CHF₃ gas. However, the deposition gas is not restricted to CHF₃ gas, and C-based gases such as CH₂F₂, C₄F₈, C₅F₈, C₄F₆, C₆F₆, CO, CH₄, CH₂Cl₂ and CH₂Br₂ can be used. Further, Si-based deposition gases such as SiF₄, SiCl₄, SiH₄ and TEOS can be used.

Even further according to the present embodiment, a process condition substantially the same as the deposition step is used for the seasoning step. However, it may take a long time before the seasoning step is completed. Therefore, in order to shorten the time thereof by efficiently depositing a deposition film on the apparatus wall, it is possible to adopt a method to increase the pressure, the flow rate and the power of the process condition for the seasoning step compared to the deposition step, to adopt a method to set the RF bias power to 0 W or to adopt a method to reduce the wall surface temperature to thereby improve the adsorption probability.

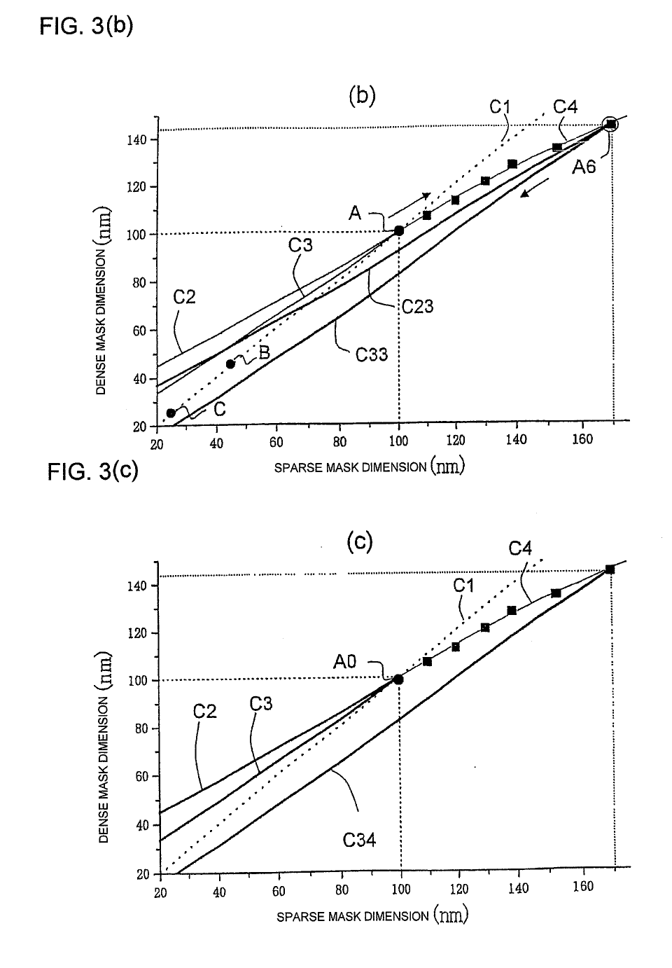

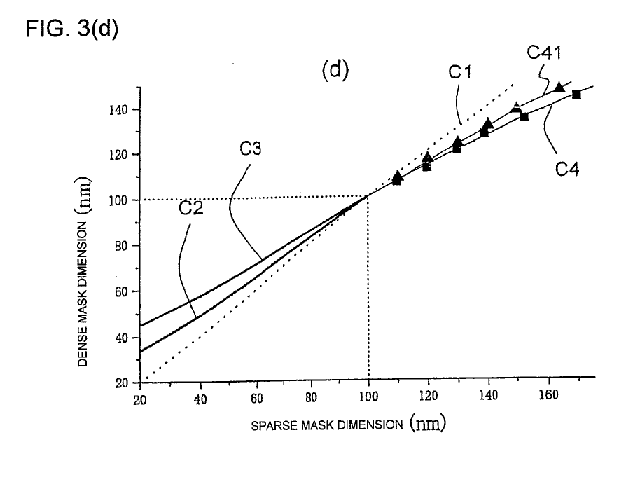

Next, the method for controlling the sparse/dense dimension using the deposition step and the trimming step will be described. FIG. 3(a) is a graph showing the transition of dimensions of the sparse mask and the dense mask achieved by performing a trimming step after performing the seasoning step S11S according to the present invention and the deposition step, wherein the initial sparse mask dimension and the dense mask dimension (sparse dense mask dimension) are 100 nm in the lithography step S1. Furthermore, the required conditions A, B and C in table 1 are shown in FIG. 3(a).

Subsequent to the lithography step S1, the cleaning step S11C and the seasoning step S11S, the deposition step S2 is performed using a deposition gas of CHF₃, a pressure of 0.2 Pa, a flow rate of 60 ml/min and an RF bias power of 10 W, and the time variation of the sparse and dense mask dimensions is examined, the result of which is shown by square plots in FIG. 3(a). It can be seen from the deposition curve C4 connecting the processing time 0 sec in which the initial sparse dense mask dimension is 100 nm and the processing time 360 sec in which the sparse mask dimension is 170 nm and the dense mask dimension is 144 nm, the dimensions of the sparse mask and dense mask are increased along with the increase in deposition time, and the sparse pattern dimension resulted in being wider than the dense pattern dimension.

Next, we have examined whether the target mask dimension of 45 nm with zero sparse dense difference according to requirement condition B of table 1 can be realized or not, and if possible, at which timing the deposition step S2 is to be switched to the trimming step S3. As a result, in the deposition step, after finishing the deposition step at a timing of time A4 in which the sparse mask dimension is 139 nm and the dense mask dimension is 127 nm, the trimming step S3 is performed to achieve the sparse mask and dense mask dimensions of 45 nm according to requirement condition B. At this time, the trimming relational curve C22 in which the sparse dense difference is greatest and the trimming relational curve C32 in which the sparse dense difference is smallest are shown in the graph. The actual trimmable region is the region surrounded by these curves and the vertical axis.

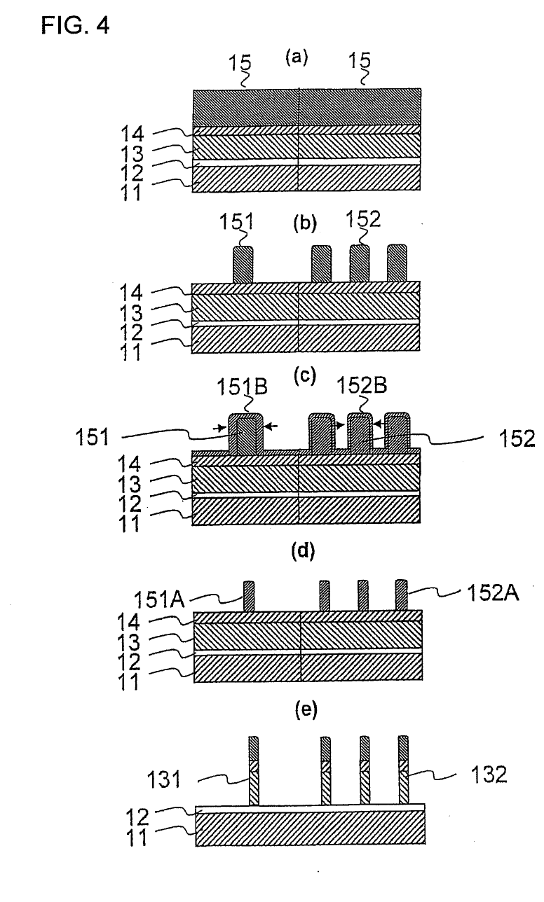

FIG. 4 shows a typified diagram of the sparse mask and dense mask patterns at this time. FIG. 4(a) is a cross-sectional view of the wafer prior to performing the lithography step. The wafer comprises, from the bottom layer, an Si substrate 11, an SiO₂ gate insulating film 12, a poly-Si gate electrode film 13, a BARL 14 and a PR mask 15. FIG. 4(b) is a cross-sectional view of the wafer after performing the lithography step, wherein the dimensions of the initial sparse mask 151 and the initial dense mask 152 are the same. FIG. 4(c) is a cross-sectional view of the wafer after the deposition step, wherein the sparse mask 151B has a dimension greater than the dense mask 152B. FIG. 4(d) is a cross-sectional view of the wafer after the trimming step, wherein the dimensions of the sparse mask 151A and the dense mask 152A are the same. FIG. 4(e) is a cross-sectional view of the wafer after the etching step, wherein the gate electrode (hereinafter referred to as gate) has a sparse gate 131 and a dense gate 132 with the same dimensions.

The present embodiment is described with reference to the structure of FIG. 4, but the present invention is also applicable to a structure that differs from the one illustrated in FIG. 4, such as of a metal gate or a 3D gate. Furthermore, the present invention is applicable not only to L/S, but also to mask shrinking technology of holes.

Similarly, a mask dimension of 25 nm and zero sparse dense difference according to requirement condition C of table 1 could be obtained by terminating the deposition step at time A6 in which the sparse mask dimension is 170 nm and the dense mask dimension is 144 nm, as shown in FIG. 3(b), and then performing the trimming step. At this time, the trimming relational curve C23 in which the sparse dense difference is greatest and the trimming relational curve C33 in which the sparse dense difference is smallest are shown in the graph. The actual trimmable region is the region surrounded by the curves and the vertical axis.

As described, by adjusting the time so that the sparse dense dimension shift quantity (increase) during the deposition step and the dimension shift quantity (decrease) of the sparse mask and the dense mask during the trimming step mutually compensate, the reproducibility of arbitrary dimensions of the sparse mask and the dense mask can be realized throughout a wide range.

In other words, by adopting this technology, as shown in FIG. 3(c), in addition to the conventional trimmable region surrounded by the trimming relational curve C2 in which the sparse dense difference is greatest, the trimming relational curve C3 in which the sparse dense difference is smallest and the vertical axis, there is added a region surrounded by the trimming relational curve C34 in which the sparse dense difference is smallest after performing the deposition step and the trimming relational curve C3 in which the sparse dense difference is smallest without performing the deposition step, so that the sparse mask dimension and the dense mask dimension can be controlled independently and arbitrarily.

Furthermore, through use of the flowchart of FIG. 1 illustrating the present embodiment, it is possible to perform the deposition step so that the deposition compensates for the roughness on the side walls of the mask pattern, so as to effectively reduce the LER (line edge roughness) and the LWR (line width roughness). This is realized since the projected portions on the side walls of the mask pattern are removed by the incident ions whereas the recessed portions are subjected to deposition of deposition radicals, so that the balance of incident ions and deposition radicals determine how much the LER and LWR are reduced.

### Embodiment 2

Next, the embodiment regarding the method for controlling the sparse pattern dimension and dense pattern dimension in the deposition step of the present invention shown in FIG. 1 will be described.

The gradient of the deposition curve C4 illustrating the time variation of the sparse mask dimension and dense mask dimension described in embodiment 1 can be controlled via apparatus control parameters such as pressure, flow rate, gas species and RF bias power. CHF₃ gas is used similarly as embodiment 1, with the pressure set to 2 Pa, the flow rate set to 100 ml/min and the RF bias voltage set to 0 W, and the time variation of the sparse mask and dense mask dimensions is examined. The examination result is shown via triangle plots in FIG. 3(d), and a deposition curve C41 connecting the examination points is drawn, similarly as embodiment 1. As can be seen from this curve, the result of the sparse pattern being wider than the dense pattern is the same as embodiment 1. However, the gradient of the deposition curve C41 differs from the gradient of the deposition curve C4 of the condition of embodiment 1, and it can be seen that the condition does not allow a large sparse dense difference.

Thus, we will now describe how the gradient of the deposition curve depends on the various parameters. Generally, when the pressure is high, the electron temperature becomes low and the dissociation of gas is suppressed, whereas when the pressure is low, the electron temperature becomes high and the dissociation of gas is advanced. Similarly, the dissociation of gas is suppressed when the flow rate is increased. The chemical species generated by the dissociation differs according to the electron temperature. The number of dangling bonds of dissociated chemical species and the energy status thereof changes the adsorption probability to the wafer pattern, by which the gradient of the deposition curve can be varied.

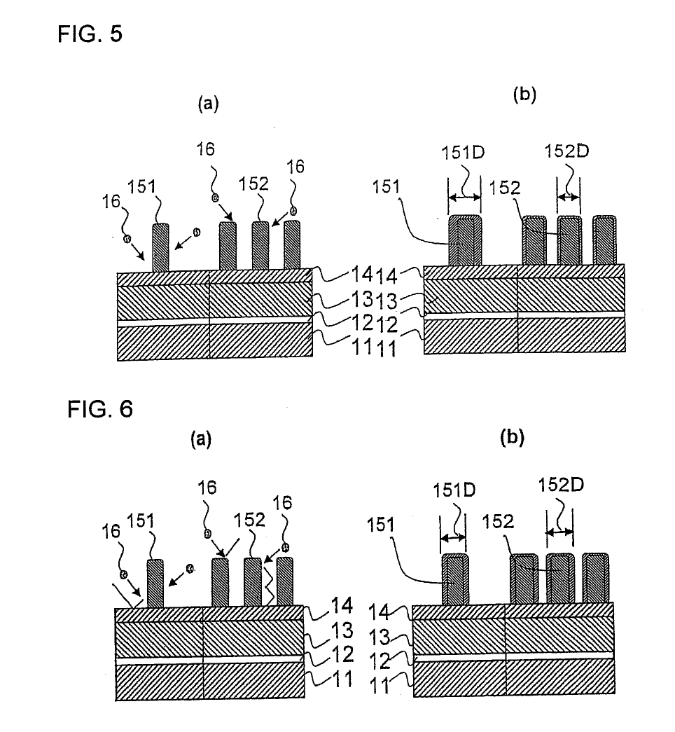

FIG. 5(a) is a view showing the state immediately after starting the deposition step when the adsorption probability is high. For example, when the adsorption probability is high, deposition radicals 16 are not sufficiently supplied to the inner portions of the channels of the fine pattern as shown in FIG. 5(a), so that the dense pattern dimension 152D becomes smaller than the sparse pattern dimension 151D after performing the deposition step shown in FIG. 5(b). Therefore, the gradient of the deposition curve is reduced and the sparse dense difference is increased.

To the contrary, FIG. 6(a) is a view showing the state immediately after starting the deposition step when the adsorption probability is low. If the adsorption probability is low, the deposition radicals 16 are supplied even to the inner portions of the channels of the fine patterns as shown in FIG. 6(a), so that the sparse pattern dimension 151D and the dense pattern dimension 152D becomes substantially equal after performing the deposition step shown in FIG. 6(b). Therefore, the gradient of the deposition curve approximates 1. In other words, the sparse dense difference is reduced.

The adsorption probability can be changed not only via pressure but also via varying the chemical species of the gas being used. Deposition gases other than CHF₃, such as CH₂F₂, C₄F₈, C₅F₈, C₄F₆, C₆F₆, CO, CH₄, CH₂Cl₂ and CH₂Br₂ can be used to vary the gradient of the deposition curve. In addition, it is also possible to use the above-mentioned gases in combination.

Similarly, the adsorption probability can also be varied by changing the electron temperature that determines the temperature of the wafer stage. When the electron temperature is lowered, the adsorption probability of deposition radicals becomes higher, and when the electron temperature is increased, the adsorption probability of deposition radicals becomes lower.

By combining these apparatus controlling parameters that change the adsorption probability, it becomes possible to vary the gradient of the deposition curve arbitrarily.

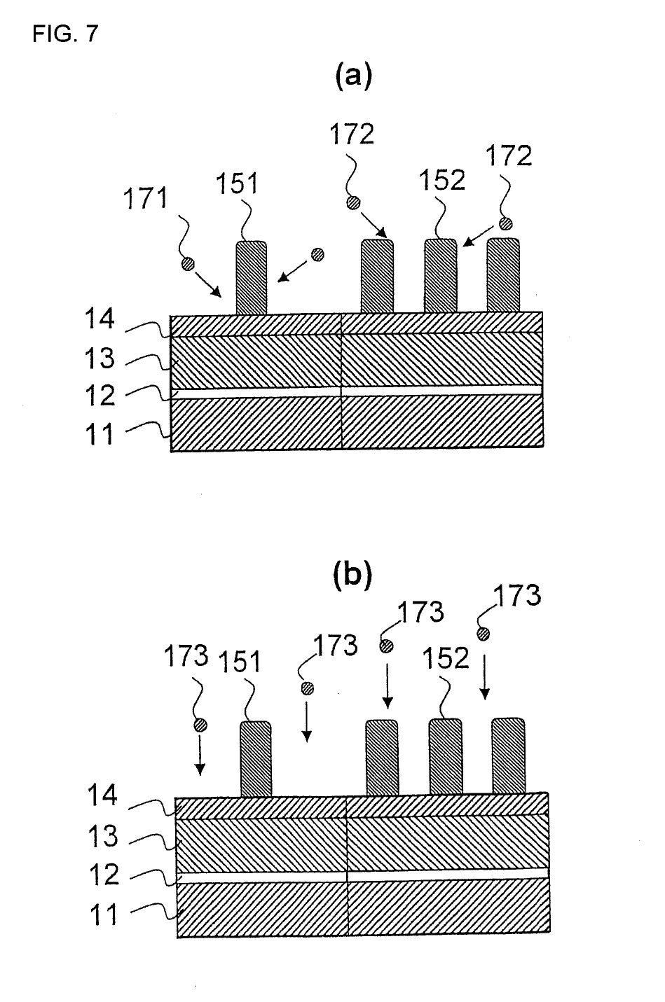

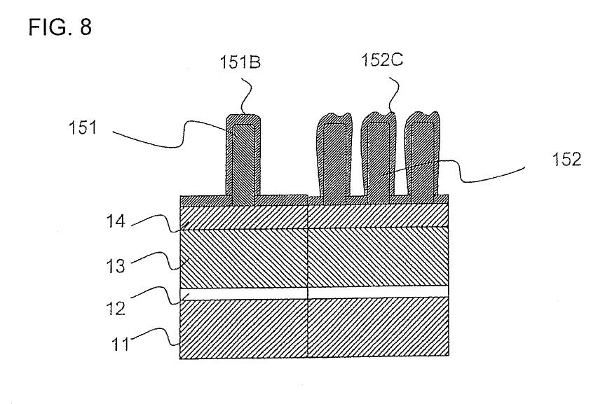

Lastly, it is possible to vary the incident angle of ions on the side walls of the pattern by gradually increasing the output of RF bias power from 0 W. FIG. 7(a) illustrates the direction of motion of ions when the RF bias power is around 0 W. The direction parallel to the wafer surface is defined as the transverse direction and the direction perpendicular thereto is defined as the vertical direction. The ions 171 having a transverse motion component in the sparse pattern have a motor component in the direction of the arrow, and will be incident on the side walls of the pattern easily. The ions 172 having a transverse motion component in the dense pattern tend to be incident on the upper portion of the mask pattern, and the probability of being incident on the side walls of the pattern is low. Therefore, if the ions are composed of depositing substances, the dimension of the sparse pattern will be easily widened than the dense pattern. In other words, the gradient of the deposition curve is reduced. To the contrary, as the RF bias power is increased, the percentage of ions 173 having a vertical motor component is increased compared to the ions having a transverse component, as shown in FIG. 7(b). Thus, ions being incident on the side walls are reduced, meaning that ions contributing to varying the dimensions are reduced. This means that the sparse dense difference is reduced. In other words, the gradient of the deposition curve approximates 1.

The method for controlling the dimensions of the sparse mask and the dense mask by performing a single deposition step and a single trimming step has been described, but there are cases in which the dimension widening quantity of the deposition step must be large in order to achieve the target sparse mask and dense mask dimensions. One possible example is when the channel between the adjacent patterns in the dense pattern is completely blocked during the deposition step. In such case, it is necessary to perform a deposition step of such a degree so as not to have the channels blocked, and then to repeatedly perform the deposition step and the trimming step for multiple number of times so as to have the dimensions gradually approximate the target sparse mask and dense mask dimensions.

According to the present invention, a seasoning step is performed before the deposition step or the trimming step, but it is also possible to omit the seasoning step, since the channels between adjacent patterns are prevented from being blocked if the deposition step utilizing an appropriate depositing condition and a trimming step are alternately performed for a multiple number of times.

Moreover, according to a condition in which the adsorption probability is high, as shown in FIG. 8, the concentration 152C of deposits on the upper side walls of the dense mask pattern may cause the channels between adjacent patterns to be gradually blocked. The increase of output of the RF bias power has an effect to perform etching via ions, that is, to etch the side walls so that the patterns are not blocked, so it is expected to maintain the opening of the dense portion.

Furthermore, since the components of the deposition film created during the deposition step and that of the PR mask are substantially the same, it is possible to reverse the order for performing the deposition step and the trimming step. However, if the order is reversed, a deposition layer is formed above the BARL 14 after performing the deposition step, so a step for removing the same is required.

Through use of the above arrangement, the dimensions of the sparse mask and the dense mask can be controlled arbitrarily, so that even if perpendicular etching is not possible during the BARL etching step S4 and the gate etching step S5 of FIG. 1, the desired sparse gate dimension and the dense gate dimension can be obtained easily. In such case, by correcting the target mask dimension after trimming, it becomes possible to realize the desired sparse gate dimension and dense gate dimension. For example, if the gate dimension subsequent to the gate etching step is shifted to the reduced side by 4 nm for the sparse mask and 3 nm for the dense mask compared to the mask dimension after the trimming step, the target mask dimension after the trimming step should simply be set greater by 4 nm for the sparse mask and 3 nm for the dense mask in advance.

The application of the method disclosed in present embodiment 2 enables to further widen the control range of the sparse mask and dense mask dimensions compared to the prior art.

### Embodiment 3

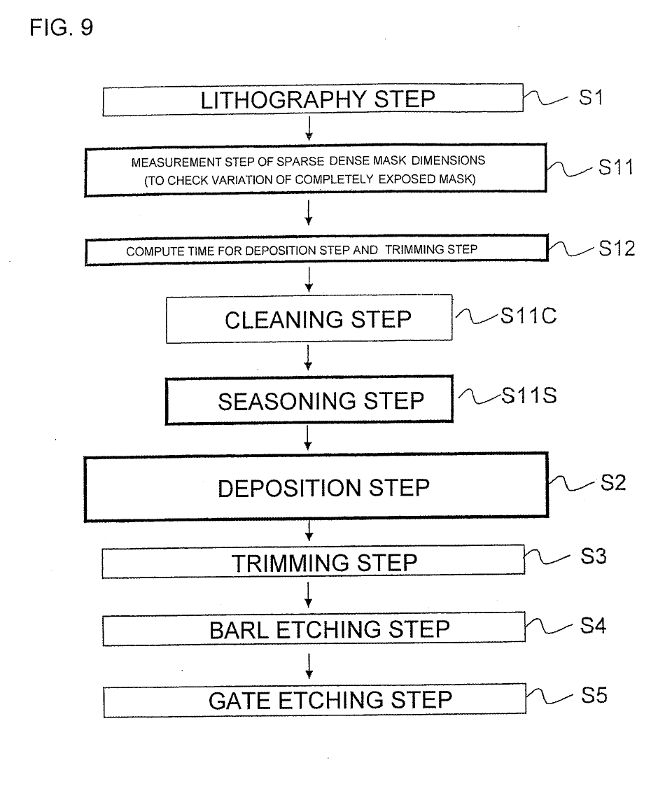

We will now describe an embodiment for stably obtaining a target sparse mask and dense mask dimension with reference to FIG. 9. The present embodiment corresponds to problem (2) to be solved. FIG. 9 is a flowchart according to the second embodiment of the present invention. A step S11 for measuring the dimensions of the sparse mask and dense mask and a step S12 for computing the time for performing the deposition step S2 and the trimming step S3 are added to the process shown in the flowchart of FIG. 1.

At first, in step S11 for measuring the sparse mask dimension and the dense mask dimension, the fluctuation of the completely exposed sparse mask and dense mask dimensions that vary with time during processing of multiple wafers is detected using OCD (optical critical dimension) or CD-SEM (critical dimension-scanning electron microscope), or CD-AFM (critical dimension-atomic force microscope), or a combination thereof.

Next, the time for performing the deposition step S2 and the trimming step S3 are computed based on the achieved sparse mask dimension and dense mask dimension (S12). During the deposition step S2, the mask dimension is increased substantially linearly with respect to time, and during the trimming step S3, the mask dimension is reduced substantially linearly with respect to time. Thus, the method for computing time can be as follows.

Assuming that during the deposition step S2, the CD shift is Dᵢₛₒ>0, D_{dense}>0 (nm), the degree of CD shift per unit time is Rᵢₛₒ, R_{dense} (nm/s) and the time of the deposition step is T_{d}, the following expression (1) is obtained by the above relationship.

[Expression 1]
Dᵢₛₒ=Rᵢₛₒ×T_{d},D_{dense}=R_{dense}×T_{d} (1)

Furthermore, assuming that during the trimming step S3, the CD shift is Trᵢₛₒ<0, Tr_{dense} (nm)<0, the degree of CD shift per unit time is R′ᵢₛₒ, R′_{dense} (nm/s) and the time of the trimming step S3 is Tₜ, the following expression (2) is obtained by the above relationship.

[Expression 2]
Trᵢₛₒ=R′ᵢₛₒ×Tₜ, Tr_{dense}R′_{dense}Tₜ (2)

When the measured sparse mask and dense mask dimensions are CDᵢₛₒ and CD_{dense} (nm), and the target sparse mask dimension after performing the deposition step S2 and the trimming step S3 is X (nm) and the dense mask dimension thereof is X+g (nm), the target mask dimensions can be expressed by the following expressions (3) and (4).

[Expression 3]
X=CDᵢₛₒ+Dᵢₛₒ+Trᵢₛₒ (3)
X+g=CD_{dense}+D_{dense}+Tr_{dense} (4)

The following expression (5) is obtained from the above expressions (3) and (4).

[Expression 4]
CDᵢₛₒ+Dᵢₛₒ+Trᵢₛₒ=CD_{dense}+D_{dense}+Tr_{dense}−g (5)

Further, the relationship between expressions (1) and (2) are applied to expression (5) to obtain the following expression (6).

[Expression 5]
(CDᵢₛₒCD_{dense})+(Rᵢₛₒ−R_{dense})T_{d}+(R′ᵢₛₒ−R″_{dense})Tₜ+g=0 (6)

Here, Td is cancelled from expressions (3) and (6) to obtain the following expression (7).
[Expression 6]

$$( {CD}_{iso} - {CD}_{dense} ) + \frac{( {R}_{iso} - {R}_{dense} ) ( X - {CD}_{iso} + {R}_{iso}^{′} {T}_{t} )}{{R}_{iso}} + ( {R}_{iso}^{′} - {R}_{dense}^{′} ) {T}_{t} + g = 0 \qquad ( 7 )$$

When expression (7) is replaced with ΔCD=CDᵢₛₒ−CD_{dense}, ΔR=Rᵢₛₒ−R_{dense}, and

ΔR′=Rᵢₛₒ−R′_{dense}, the following expression (8) is obtained.

[Expression 7]

$$( Δ CD ) + \frac{( Δ R ) ( X - {CD}_{iso} + {R}_{iso}^{′} {T}_{t} )}{{R}_{iso}} + ( Δ {R}^{′} ) {T}_{t} + g = 0 \qquad ( 8 )$$

If Rᵢₛₒ, R_{dense}, R′ᵢₛₒ, R′_{dense}, CDᵢₛₒ and CD_{dense} are measured in advance, it is recognized that in order to achieve the target sparse mask and dense mask dimensions X and X+g, the deposition process should be performed for T_{d} seconds and the trimming process should be performed for Tₜ seconds, based on expressions (7) and (3). As described above, by computing the times for performing the deposition step S2 and the trimming step S3 and to perform the deposition step and the trimming step for a suitable period of time, it becomes possible to cancel the fluctuation of the completely exposed sparse mask dimension and dense mask dimension that vary with time. Therefore, it becomes possible to realize a target sparse mask dimension and a target dense mask dimension.

Furthermore, the values of the above-mentioned ΔR=Rᵢₛₒ−R_{dense} and ΔR′=R′ᵢₛₒ−R′_{dense} can also be determined based on emission prediction of plasma during the deposition step and the trimming step, or based on prediction utilizing a profile simulation technology. Furthermore, Tₜ and T_{d} can also be computed based solely on profile simulation technology or by combining the same with emission analysis.

Incidentally, according to the second term and the third term of expression (3), if ΔR=0 and ΔR′=0, T_{d} and Tₜ cannot be calculated and the dimension cannot be controlled. The CD shifts of the sparse mask and the dense mask per unit time during the deposition step and the trimming step will generally not be of the same value, but if they are of close values, the time T_{d} and Tₜ required for controlling the sparse dense difference will be increased. Therefore, a means for varying the gradient of the deposition curve by adjusting the parameters of the deposition step is effective, as disclosed in embodiment 2.

### Embodiment 4

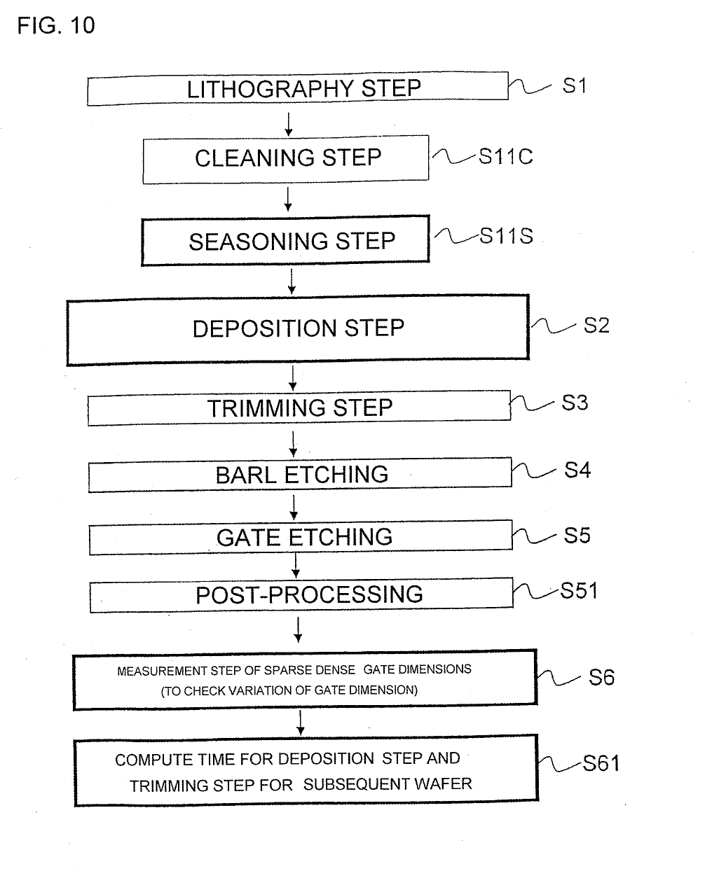

Now, with reference to FIG. 10, an embodiment for obtaining the target sparse mask and dense mask gate dimensions in a stable manner with respect to the fluctuation of gate dimensions of the sparse mask and dense mask occurring with time will be described. This embodiment corresponds to problem (3) to be solved. FIG. 10 is a flowchart according to embodiment 3 of the present invention. In the present embodiment, a post-processing step (S51) after the gate etching process, a measurement step (S6) for measuring the gate dimension of the sparse mask region (hereinafter referred to as sparse gate dimension) and the gate dimension of the dense mask region (hereinafter referred to as dense gate dimension) and a step (S61) for computing the time for performing the deposition step and the trimming step for the subsequent wafer are added to the process illustrated in FIG. 9.

At first, after completing the gate etching step S5 and the post-processing step (S51) such as ashing, the fluctuation of the sparse gate dimension and the dense gate dimension are detected via OCD or CD-SEM, CD-AFM or a combination thereof in the step for measuring the sparse gate dimension and dense gate dimension.

Based on the fluctuation information of the sparse gate dimension and the dense gate dimension being detected, the correction values of the target sparse mask dimension and target dense mask dimension are computed, and the time for performing the deposition step and trimming step for realizing the new target sparse mask dimension and dense mask dimension is computed (S61) The result is reflected on the subsequent wafer or the subsequent lot to suppress long-term fluctuation of the sparse gate dimension and the dense gate dimension, so as to stably obtain the target sparse and dense gate dimensions.

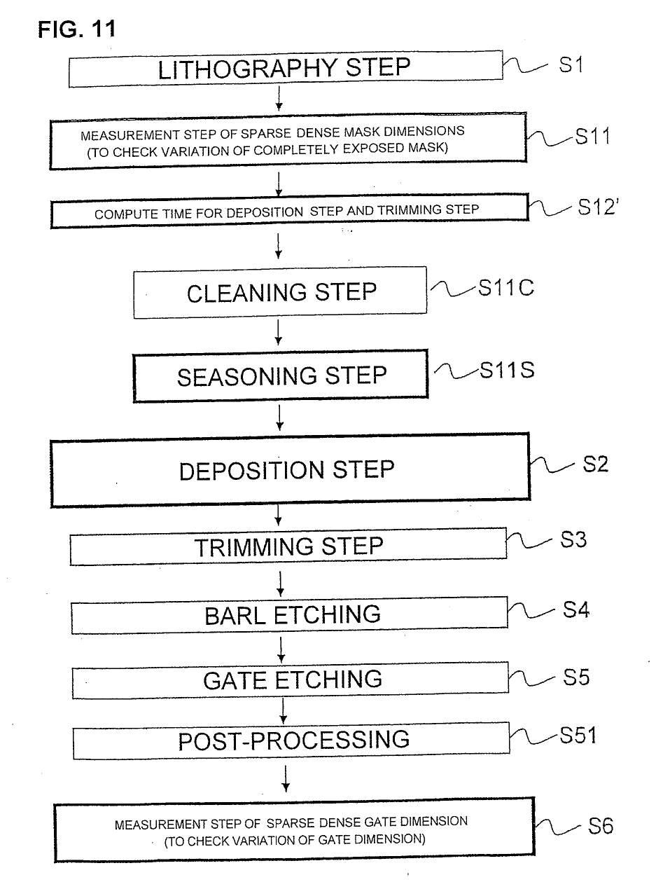

Further, FIG. 11 is a flowchart of the fourth embodiment combining embodiment 4 with embodiment 5 described later. At first, steps S1, S11C, S11S, S2, S3, S4, S5, S51 and S6 are the same as embodiment 4 illustrated in FIG. 10, whereas a step S11 for measuring the sparse/dense mask dimensions and the method (S12′) for computing the times for the deposition step and the trimming step differ from embodiment 4. Based on the sparse mask and dense mask dimension fluctuation according to the measurement step S11 of the sparse mask dimension and dense mask dimension and the sparse mask and dense mask dimension fluctuation according to the measurement step S6 for measuring the sparse gate dimension and dense gate dimension, the target sparse mask dimension and the target dense mask dimension are determined. The times for the deposition step and the trimming step for realizing the determined target sparse mask dimension and target dense mask dimension are computed (S12′), so as to obtain the target sparse gate dimension and target dense gate dimension with respect to the fluctuations of the exposure mask dimension, the sparse gate dimension and the dense gate dimension, respectively.

Up to the present embodiment, methods for controlling the sparse mask dimension, the dense mask dimension, the sparse gate dimension and the dense gate dimension by varying the etching conditions and time of the deposition step have been described, but the etching conditions and time for the trimming step S3 and the BARL etching step S4 can also be utilized to control the sparse mask dimension and the dense mask dimension. However, from the viewpoint of improving throughput, an apparatus is desired that can change the electrode temperature quickly during each step from the deposition step to the gate etching step. One reason for this is that during each step, the adsorption probability can be varied by the electrode temperature, by which the range of control of the sparse and dense mask dimensions can be widened. Another reason for this is since during the gate etching step, the most appropriate electrode temperature is determined to achieve a perpendicular profile, but this temperature does not necessarily correspond to the electrode temperature for the deposition step or the trimming step.

### Embodiment 5

Up to now, the control of the sparse mask dimension and the dense mask dimension of a gate composed, from the lower layer, of an Si substrate, SiO₂, Poly-Si, BARL and PR mask have been described. The following embodiment shows that the sparse mask dimension and the dense mask dimension can be controlled for objects having other structures and composed of other materials.

Since the sparse mask dimension and the dense mask dimension can be controlled arbitrarily according to the present invention, the materials constituting the layers lower than the mask can be anything. In other words, the portion of the sparse mask dimension and dense mask dimension being varied by etching of the materials constituting the layers lower than the mask can be corrected by correcting the sparse mask dimension and the dense mask dimension to achieve the target sparse gate dimension and dense gate dimension. In other words, the present invention can cope with any material constituting the gate, the antireflection film and the like. Therefore, the gate can be a metal gate composed of metal materials such as Mo, TiN, TaN, TaSiN, TiSiN, TaC, HfN, HfSiN and WSi, or a full silicide gate composed of NiSi, PtSi and the like. Other possible mask materials include amorphous carbon, SiON, Ti, SiO₂ and SiOC. These mask materials are mainly used as a part of the multilayer mask structure. The antireflection film can be composed of organic materials such as BARC, but in that case, it must be taken into consideration that BARC has a composition substantially equal to the PR mask.

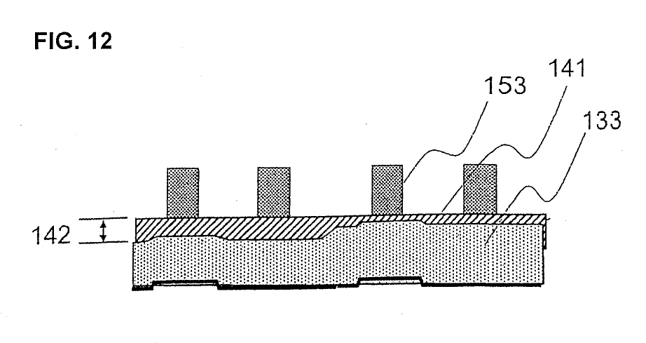

FIG. 12 is a cross-sectional view of a wafer composed, from the bottom layer, of a gate electrode film 133, a BARC 141 and a PR mask 153. If the antireflection film disposed as a lower layer of the PR mask is BARC, as illustrated, the BARC is simultaneously etched when the mask dimension is changed during the trimming step. When the difference between the sparse mask dimension and dense mask dimension per unit time during the trimming process (also referred to as BARC ME) is defined as ΔR_{ME} and the difference between the sparse mask dimension and the dense mask dimension per unit time during BARC OE (overetching) is defined as ΔR_{OE}, it is assumed that the value of ΔR_{OE} is substantially equal to the trimming step of the PR mask in which the antireflection film is BARL. In other words, during the trimming step in which the antireflection film is BARC, two steps of ΔR_{ME} and ΔR_{OE} can be used to control the sparse mask dimension and the dense mask dimension. However, there is a thickness distribution of BARC 141 accompanying the generation of steps of the gate electrode due to STI (shallow trench isolation), and the OE time is determined so that the deepest portion 142 of the BARC is etched and removed, so the control must be performed within this time range.

If a multilayered mask structure is adopted, it is also possible to control the sparse mask dimension and the dense mask dimension in a multi-step manner for each mask layer. The structure thereof can be PR mask/BARC/SiON/amorphous carbon.

Furthermore, if hard masks such as SiO₂, SiON, HfSiO and HfSiOCl are used as mask material instead of the PR mask, a deposition step similar to the deposition step of the PR mask can be performed by using an Si-based gas such as SiF₄, SiCl₄, SiH₄ or TEOS or a combination thereof.

### Embodiment 6

We will now illustrate the sixth embodiment which is an indicator for controlling the in-plane distribution of wafer pattern which may become a problem for controlling the sparse mask dimension and dense mask dimension.

Generally during etching, ions and radicals generated in the plasma become incident on the semiconductor substrate, causing surface reaction with Si and other organic materials being the processing object.

Furthermore, the reaction products generated by etching become incident on the semiconductor substrate again and disturb the etching reaction. The surface reaction and the adhesion of radicals and reaction products depend greatly on the semiconductor substrate temperature. Therefore, the process dimension and the process profile are varied not only by the flux of ions, radicals and reaction products being incident on the semiconductor substrate but also on the semiconductor substrate temperature. Usually, it is possible to control the in-plane distribution of flux of ions and radicals being incident on the semiconductor substrate by controlling the plasma distribution, but the distribution of reaction products is basically diffused, and it is difficult to control the distribution thereof. Therefore, the method of controlling the process dimension and process profile by controlling the temperature distribution of the semiconductor substrate is an extremely effective method to improve the in-plane uniformity of process accuracy of the semiconductor substrate.

In the deposition step S2 for depositing a protection film, the main important surface reaction is the carbon-based reaction products generated uniformly in the plasma adhering to the PR mask, so it is preferable for the in-plane temperature distribution to be uniform.

On the other hand, in the gate etching process, the complex reaction between poly-Si and the ions, radicals and Si reaction products being incident on the poly-Si film is dominant, so it is necessary to take into consideration the semiconductor substrate in-plane distribution of each particle being incident on the substrate upon performing temperature distribution control. For example, the reattachment of reaction products take a “center-high distribution” in which the reattachment is gradually reduced from the inner side of the wafer surface toward the outer circumference, so that by reducing the temperature distribution of the wafer stage from the inner side toward the outer circumference, it becomes possible to uniformize the reattachment of reaction products in the wafer plane. Thus, the in-plane dimension can be made more uniform.

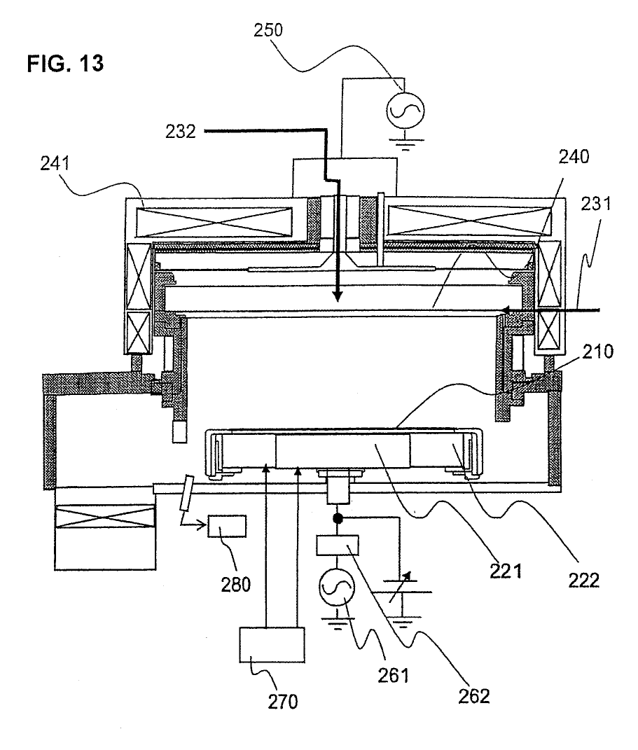

FIG. 13 shows one example of an etching apparatus to which the present invention is applied. The etching apparatus comprises an electrode for placing a processing wafer 210 in a processing chamber, a gas feed port, an electromagnet 241, a high-frequency power supply 250, an RF and bias power supply 261 and a matching unit 262, a circulator 270, and an emission spectrometer 280. An inner electrode 221 and an outer electrode 222 are provided under the processing wafer 210. The gas feed port is composed of an inner gas feed port 232 and an outer gas feed port 231.

The temperature and temperature distribution of the wafer stage for placing the wafer can be controlled for example by using multiple refrigerants, by controlling the He pressure on the rear surface, or by using heaters. For example, the etching apparatus of FIG. 13 has an inner electrode 221 and an outer electrode 222 provided below the processing wafer 210.

Another possible method for realizing in-plane uniformity is to use two or more lines of gas feed ports to vary the distribution of reaction radicals and deposition radicals. The in-plane uniformity can be realized by controlling the reaction radicals to be higher at the center, the deposition radicals to be higher at the circumference, or by combining both to correspond to the “center-high distribution” of reaction products. For example, the etching apparatus shown in FIG. 13 has two lines of gas feed ports, an inner gas feed port 232 and an outer gas feed port 231.

Based on the above, by taking into consideration the in-plane uniformity and controlling the sparse/dense dimensions, it becomes possible to achieve the desired sparse/dense mask dimensions and gate dimensions throughout the whole surface of the wafer.

### Embodiment 7

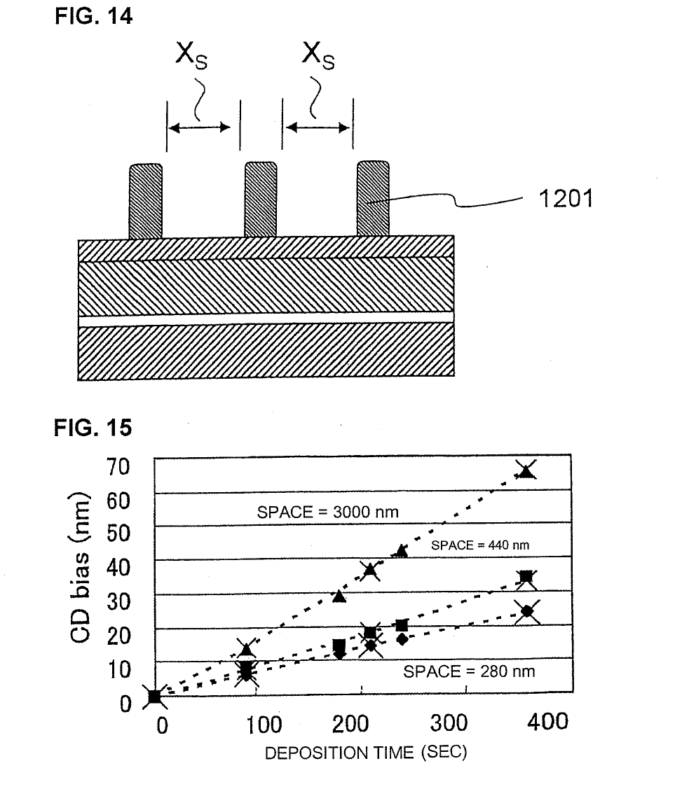

The present embodiment describes an effective method for corresponding to needs to fabricate small quantities of large varieties of products. This embodiment corresponds to problem (4) to be solved. FIG. 14 is a view for describing the definition of space. As shown in FIG. 14, the width Xₛ between adjacent masks 1201 is defined as space.

TABLE 2

| | | DEPOSITION TIME | | |
|---|---|---|---|---|
| | | 90 SEC | 210 SEC | 390 SEC |
| SPACE | 200 nm | 6 nm | 13 nm | 21 nm |
| | 440 nm | 7 nm | 17 nm | 30 nm |
| | 500 nm | 8 nm | 19 nm | 34 nm |
| | 1000 nm | 10 nm | 27 nm | 54 nm |
| | 2200 nm | 14 nm | 36 nm | 65 nm |
| | 5000 nm | 14 nm | 36 nm | 65 nm |

Table 2 shows the CD bias of the mask disposed in a certain space with respect to the size of each space and each deposition time, when the mask height is 200 nm. As a result, it has been discovered that there exists a rule for accurately expressing the CD bias as a function of space Xₛ (nm) and deposition time T_{d}, as shown in the following expression (9).

[Expression 8]
CD bias=f(Xₛ,T_{d}) (9)

By computing this relational expression based on experimental values, it becomes possible to estimate the CD bias in all the spaces. In other words, by storing data per each process condition of the deposition step, it becomes possible to estimate the CD bias even for wafers having mask dimensions and mask densities with spaces that are never subjected to the deposition step, and to realize the estimated CD bias. Three or more experimental data are required for deriving the sparse dense relational expression. However, in order to achieve an accurate sparse dense relational expression, it is preferable to acquire as much number of spaces and CD biases per deposition time as possible.

Now, through use of a wafer having an initial mask dimension of 40 nm, the deposition time dependency of the CD bias wherein the spaces are 280 nm, 440 nm and 3000 nm are acquired through experiments. FIG. 15 shows a graph illustrating an estimated value based on the sparse dense gradient expression and the experimental value of the deposition time dependency (90, 210 and 390 seconds) of the CD bias wherein the spaces are 280 nm, 440 nm and 3000 nm. This graph is hereinafter referred to as a sparse dense dimension graph.

The estimated CD bias is shown via X-marked plots. As a result, the estimated CD bias was linear with respect to the deposition time. Thus, the linear approximation of the time dependency of the estimated CD bias is shown via dotted lines. One method for improving the approximation accuracy is to create many sparse dense relational expressions for each deposition time. Another possible method is to create a polynomial equation by performing fitting. Further in the graph, the experimental values of the CD bias for spaces of 280 nm, 440 nm and 3000 nm are shown via plots of rhombuses, squares and triangles, respectively. As a result of comparing the CD biases of the estimated approximate curve and the experimental value, it has been discovered that the error was within +−2.0 nm, which is of equivalent level as the error of the CD-SEM. It is considered that the error can be further reduced by performing a multipoint measurement of the mask dimension within the wafer plane using CD-SEM and averaging the same, and by setting a long measurement line of approximately 2μ.

As described, the sparse dense relational expression can be obtained by measuring the CD bias at three or more points of different spaces at a certain deposition time, and by performing fitting. Since the CD bias in all spaces during a certain deposition time can be estimated with high accuracy by using the sparse dense relational expression, it becomes possible to realize a desired sparse/dense mask dimension for any wafer having any sparse/dense mask dimension and density. Further, the time dependency of the CD bias for all the spaces can be recognized by acquiring the sparse dense relational expression of various deposition times in advance.

In the present embodiment, the sparse dense relational expression is obtained from the relationship between the size of the spaces in which the mask height is 200 nm and the CD bias of the mask in that space. The sparse dense relational expression can be expressed using the sparse dense relational expression regardless of the mask height. In the present experiment, the target was a simple DRAM with much L&S or a flash memory, so the sparse dense relational expression was expressed as a function of space. On the other hand, as for logic, SRAM and the like, the sparse dense relational expression can be utilized as a function of the area density of the mask instead of space. It is also possible to utilize the ratio of mask height and space (aspect ratio) instead of space.

Moreover, as have already been described that the gradient of the deposition curve related to sparse/dense according to the previous embodiment can be varied using conditions such as the gas species, the gas flowrate, the gas pressure, the electrode temperature and the RF bias power, it can be easily recognized that the relationship between the space and the CD bias expressed via the sparse dense relational expression is also controllable using these conditions. Furthermore, the present invention enables to create a sparse dense relational expression for the trimming step similar to the deposition step. Accordingly, by utilizing the sparse dense relational expression not only for the deposition step but also for the trimming step, it becomes possible to realize a sparse/dense mask dimension with superior repeatability for processing small amounts of large varieties of products while performing CD control for an arbitrary L/S.

### Embodiment 8

Embodiment 1 discloses a method for introducing a seasoning step and controlling the end point of the deposition step by time. It has been explained that if the seasoning step is not performed before the deposition step, the sparse/dense mask dimension has deteriorated linearity with respect to the deposition time dependency, as shown in FIG. 16. This can also be described with reference to FIG. 15 (in the present embodiment, the mask having a 3000 nm space interval is defined as sparse and the mask having a 280 nm space interval is defined as dense), wherein the deposition was performed with the deposition time set to 210 seconds with the target sparse dimension set to 36.1 nm and the target dense dimension set to 14.3 nm, but resulting for example in the increase of the sparse/dense mask dimension corresponding to 180 seconds (with a sparse dimension of 29.0 nm and a dense dimension of 12.0 nm). On the other hand, there are cases in which the dimensions are increased too much.

The present embodiment illustrates an example enabling to increase the sparse/dense mask dimension to the desired dimension with high accuracy, by controlling the endpoint of the deposition step using the film thickness measured via a film thickness interferometer, and by utilizing a sparse dense relational expression, without performing the seasoning step.

FIG. 17 is a view showing the frame format of the sparse mask pattern at a certain time during the deposition step. During the deposition step, the deposition film is deposited not only on the side walls 2301 of the sparse mask pattern but also on the open space 2302. In the present experiment, the reflected interference light of the plasma emission from the wafer is used to measure the film thickness of the open space. Of course, it is possible to adopt a method to use a film thickness monitor to detect the reflected interference light from the wafer using the light source irradiated on the wafer. Furthermore, the film thickness monitor can be used to detect deposits deposited other than on the wafer, such as on the reactor wall or on the susceptor.

As a result of examining the relationship between the film thickness 2303 deposited on the open space and the CD bias of the sparse mask pattern, it has been discovered that they have an extremely good correlation. As a result of experiment, it has been discovered that the sparse CD bias is increased linearly with respect to the film thickness deposited on the open space portion. In other words, the relationship between the sparse CD bias and the dense CD bias can be expressed via the following expression (10).

[Expression 9]
{sparse CD bias}=a×{open space film thickness} (10)

Here, “a” is defined as the conversion factor. In the process condition of the present embodiment, the value of “a” is known to be 0.5331. This “a” is determined per each process condition.

By computing the value of “a” per each process condition in advance, the sparse CD bias can be estimated by monitoring the film thickness in real time during the deposition step. By setting the end point based on the estimated sparse CD bias, it becomes possible to obtain the desired sparse CD bias with high accuracy.

Incidentally, if the sparse CD bias is acquired, the CD bias of all the spaces can be estimated using the deposition time dependency of the CD bias (FIG. 15) which can be computed based on the sparse dense relational expression described in the former embodiment. Through use of this method, it becomes possible to set the end point when the CD bias in an arbitrary space reaches a desired dimension.

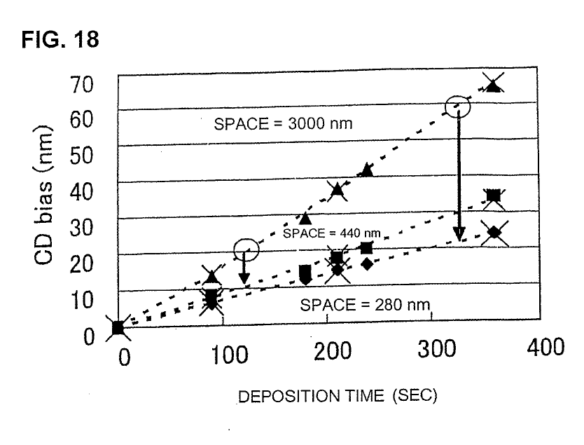

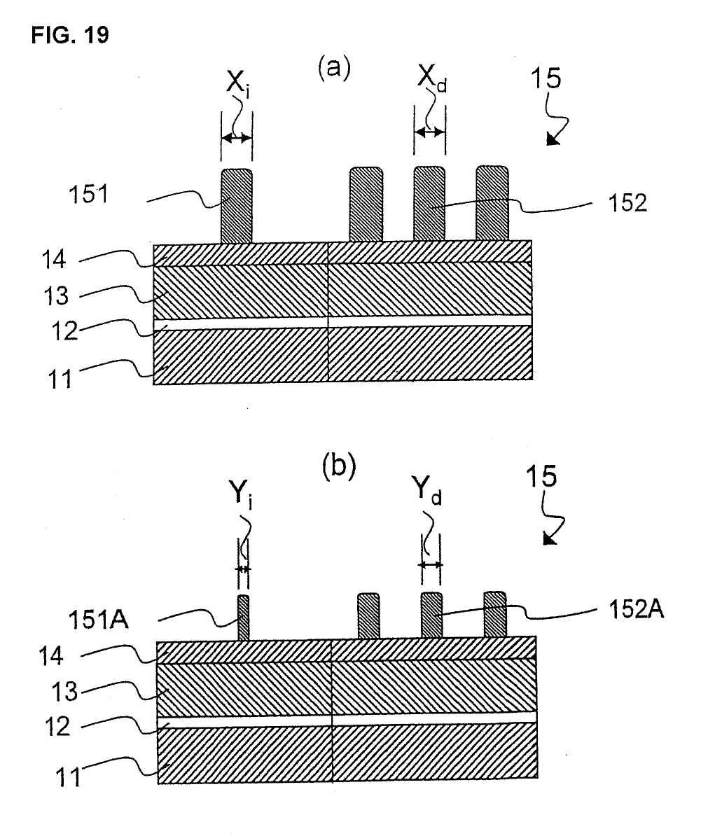

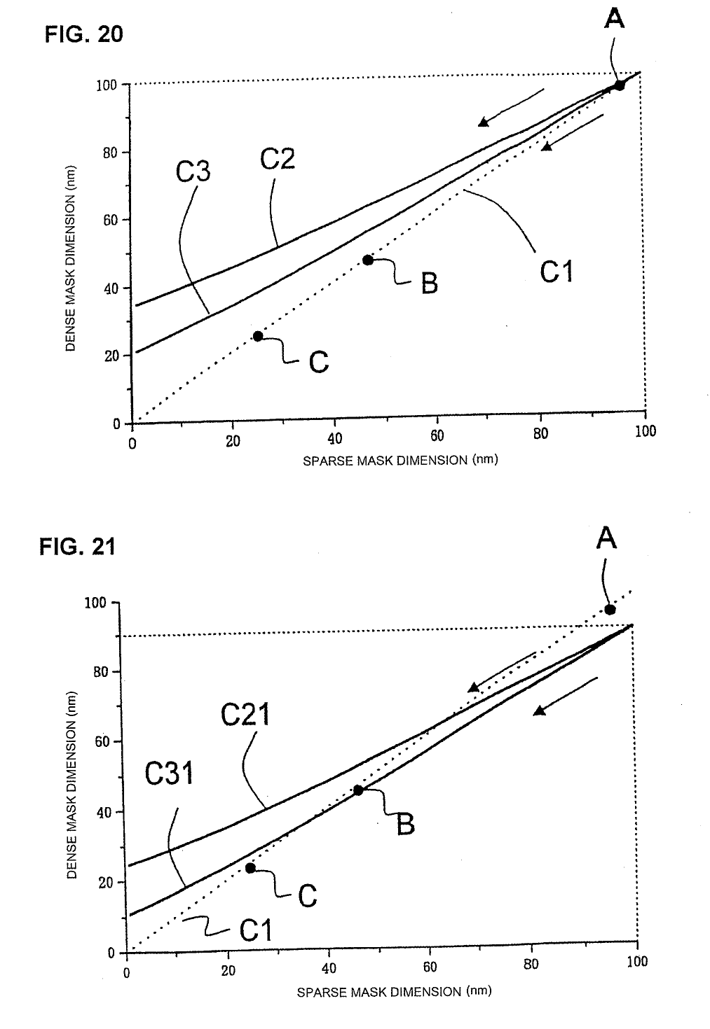

FIG. 18 shows one example of a view describing the method for setting the end point using an arbitrary space. For example, if the desired CD bias in space 440 nm is 10 nm, the end point should be set when the sparse CD bias reaches 20 nm. In another example, if the desired CD bias in space 280 nm is 22 nm, the end point should be set when the sparse CD bias reaches 69 nm.

As described, by setting the end point using the method for monitoring in real time the sparse dimension converted via the film thickness of the open space portion and the sparse dense dimension graph estimated from the sparse dense relational expression, it becomes possible to obtain the mask dimension of the desired space with high accuracy.

1. A semiconductor fabrication method for processing a sample via dry etching, comprising:
prior to performing dry etching, performing a seasoning step followed by a deposition step using a deposition gas and a trimming step, or performing a seasoning step followed by a trimming step and a deposition step using a deposition gas.

2. The semiconductor fabrication method according to claim 1, wherein
the deposition step and the trimming step are alternately repeated following the seasoning step.

3. The semiconductor fabrication method according to claim 1, wherein
the deposition gas used in the deposition step includes at least one gas selected from a group consisting of CHF₃, CH₂F₂, C₄F₈, C₅F₈, C₄F₆, C₆F₆, CO, CH₄, CH₂Cl₂, CH₂Br₂, SiF₄, SiCl₄, SiH₄ and TEOS.

4. The semiconductor fabrication method according to claim 1, wherein
at least one of apparatus parameters for controlling a condition of the deposition step, which are time, gas species, gas pressure, gas flow rate, RF (radio frequency) bias power and electrode temperature, is varied.

5. The semiconductor fabrication method according to claim 1, further comprising:
a mask pattern dimension measurement step for measuring a dimension formation result of a sparse mask pattern and a dense mask pattern subsequent to a lithography step; and
based on the mask pattern dimension measurement result, determining the conditions of the deposition step and the trimming step following the seasoning step for the subsequent semiconductor fabrication.

6. The semiconductor fabrication method according to claim 1, further comprising:
a gate electrode dimension measurement step for measuring the dimensions of a sparse pattern and a dense pattern of a gate electrode after forming the gate electrode; and
based on the gate electrode dimension measurement result, determining the etching conditions of the deposition step and the trimming step following the seasoning step for the subsequent semiconductor fabrication.

7. The semiconductor fabrication method according to claim 1, further comprising:
a mask pattern dimension measurement step for measuring a dimension formation result of a sparse mask pattern and a dense mask pattern subsequent to a lithography step;
a gate electrode dimension measurement step for measuring the dimensions of a sparse pattern and a dense pattern of a gate electrode after forming the gate electrode; and
based on the mask pattern dimension measurement result and the gate electrode dimension measurement result, determining the conditions of the deposition step and the trimming step following the seasoning step for the subsequent semiconductor fabrication.

8. The semiconductor fabrication method according to claim 1, further comprising:
a step for controlling an electrode temperature distribution and a step for controlling a gas distribution; wherein
at least either the wafer in-plane temperature distribution or the gas distribution is varied out of the various apparatus parameters for controlling the conditions of the deposition step, the trimming step or the dry etching step following the seasoning step for the subsequent semiconductor fabrication.

9. A semiconductor fabrication method for processing a sample via dry etching, comprising:
prior to performing dry etching, performing a deposition step using a deposition gas and a trimming step, or performing a trimming step and a deposition step using a deposition gas.

10. The semiconductor fabrication method according to claim 9, wherein
the deposition step and the trimming step are alternately repeated following a lithography step.

11. An etching system for controlling an etching apparatus, comprising:
an apparatus for measuring dimensions of a sparse pattern and a dense pattern of a mask pattern;
an etching apparatus performing deposition using deposition gas subsequent to a seasoning step and either before or after performing trimming of the mask pattern, and then performing etching of a layer to be processed disposed below the mask pattern;
a control unit for deriving an expression for computing conditions for the deposition step using the deposition gas and a following trimming step with respect to dimensions of a sparse mask and a dense mask of the target mask pattern, and computing the result thereof; and
a feed forward-feed back system for transmitting to the control unit at least one measurement result of the measurement performed by the apparatus for measuring the dimensions of the sparse pattern and the dense pattern, the apparatus measuring either the dimensions of the sparse mask and the dense mask or the dimensions of the sparse pattern and the dense pattern of a gate electrode after forming the gate electrode.

12. The etching system according to claim 11, wherein
the deposition gas used in the deposition step includes at least one gas selected from a group consisting of CHF₃, CH₂F₂, C₄F₈, C₅F₈, C₄F₆, C₆F₆, CO, CH₄, CH₂Cl₂, CH₂Br₂, SiF₄, SiCl₄, SiH₄ and TEOS.
